(19) United States
(12) Patent Application Publication
(10) Pub. No.: US 2015/0323568 A1
(43) Pub. Date: Nov. 12, 2015

(54) ARRANGEMENT FOR MEASURING CURRENT

(71) Applicant: SENSITEC GMBH, Lahnau (DE)

(72) Inventor: Jochen SCHMITT, Biedenkopf (DE)

(73) Assignee: SENSITEC GMBH, Lahnau (DE)

(21) Appl. No.: 14/410,087

(22) PCT Filed: Jun. 27, 2013
(86) PCT No.: PCT/EP2013/063557

§ 371 Date: Dec. 21, 2014

(30) Foreign Application Priority Data
Jun. 27, 2012 (DE) 10 2012 012 759.6

(51) Int. Cl. G01R 15/20; G01R 19/00; G01R 1/04

(52) U.S. Cl. CPC G01R 15/205; G01R 1/0408; G01R 19/0092

(57) ABSTRACT

An arrangement is provided for measuring electrical currents and is based on magnetic fields. By at least one sensor element which is sensitive to magnetic fields, current is measured in a bent conductor element including a conductor section which is active in terms of current measurement and at least one conductor section which is parasitic in terms of current measurement. In the region of the conductor section which is active in terms of current measurement, the sensor element is oriented, i.e. twisted, tilted, and/or height-adjusted with respect to the conductor section which is parasitic in terms of current measurement, such that the magnetic field of the conductor section which is active in terms of current measurement is oriented substantially in the direction of sensitivity and the magnetic field of the conductor section which is parasitic in terms of current measurement is oriented substantially not in the direction of sensitivity.

### BACKGROUND AND SUMMARY

The present invention relates to an arrangement for the indirect measurement of a current in a conductor by detection of the magnetic field surrounding the current-carrying conductor.

Arrangements of this type are known from the prior art. Thus DE4300605 describes an arrangement in which a sensor chip is provided in a gradiometer arrangement and mounted on a U-shaped conductor element. This exploits the fact that the gradiometer arrangement described is largely insensitive to homogeneous interfering fields at the location of the sensor element. In order to generate the smallest possible inhomogeneous interfering fields due to currents through the connecting bridge between the legs of the U-conductor or the feed to the U-conductor at the location of the sensor, the length of the legs of the U-shaped conductor is generally selected to be large in comparison to the extent of the elements sensitive to magnetic fields on the sensor chip.

Furthermore, in arrangements of this type, in particular in the case of sensors that exploit the anisotropic magnetoresistive effect (AMR effect), auxiliary magnets are provided close to the magnetic-field-sensitive layers, and are responsible for a stabilization or a base-magnetization of the magnetic-field-sensitive layers on the sensor chip. With an increasing miniaturization of a sensor arrangement of this type, the interfering field components caused for example by the currents in the connecting bridge between the legs of the U-conductor can adopt a magnitude that leads to a change, or to the “tipping over” of the magnetization of the magnetic-field-sensitive layers. This leads to serious errors in the current measurement and must therefore be avoided.

Based on the above-mentioned prior art, it is desirable to reduce the disadvantages of the known arrangements and methods.

In a first aspect, an arrangement is proposed for the measurement of electrical currents based on magnetic fields by means of at least one magnetic-field-sensitive sensor element in an angled, in particular U-shaped, conductor element, comprising at least one conductor section active in current measurement and at least one conductor section parasitic to current measurement. The sensor element is arranged in the region of the conductor section active in current measurement such that the magnetic field of the conductor section active in current measurement generates a major change in the sensor value, in particular a major change in the resistance, and the magnetic field of the conductor section parasitic to current measurement generates, due to the spatial orientation of the sensor element relative to the conductor section parasitic to current measurement and/or by field compensation effects of further current-carrying elements, minor and substantially no change in the sensor value. The invention, according to an aspect thereof, thus relates to a current measurement arrangement based on a magnetic field measurement in which a sensor element is spatially arranged at a conductor section of a current conductor such that parasitic magnetic fields caused by conductor sections that do not correspond to the conductor section to be measured do not penetrate the sensor element or penetrate in a direction such that they do not generate any change in the sensor value in the sensor element. The arrangement can be achieved by inclining a sensitivity direction of the sensor element relative to a current conduction direction of the conductor sections parasitic to current measurement (supply conductor sections), by turning and/or displacing the vertical levels of a layer of sensor structures sensitive to magnetic fields relative to a concentrated line current through the parasitic conductor sections. The said measures of angular inclination, turning relative to a current flow direction, vertical displacement and magnetic field compensation, can be applied individually or in combination. It is ensured by these measures that parasitic magnetic field components firstly negatively affect internal magnetization states of resistive elements of sensor structures and secondly exert no influence on the sensor value change/resistance value change, in order to achieve a linear and assignable behaviour of the sensor value.

In accordance with an aspect of the invention, the sensor element has at least one sensitivity direction in which magnetic field components cause a major change in the sensor value, where the sensor element is oriented in such a way in the region of the conductor section active in current measurement, in particular turned, inclined and/or vertically moved relative to the conductor section parasitic to current measurement, so that the magnetic field of the conductor section active in current measurement is oriented substantially in the sensitivity direction, and the magnetic field of the conductor section parasitic to current measurement is oriented substantially not in the sensitivity direction, in particular at right angles to the sensitivity direction. A magnetoresistive sensor element is thus considered that has at least one magnetic-field-sensitive orientation plane, to which a sensitivity direction is normal, which when penetrated by a magnetic flux in the sensitivity direction causes a change in the sensor value, usually a change in the resistance of the sensor element. At least one further magnetic-field-neutral sorientation plane of the sensor element, whose normal is usually oriented at right angles to the sensitivity direction, is insensitive to a change in the magnetic field. Magnetic fields which pass normally through the magnetic-field-neutral orientation plane do not change the sensor value, in particular do not change a resistance value of the sensor element.

It is proposed that the sensitivity direction is oriented in such a way by a spatial positioning of the sensor element relative to the conductor sections parasitic to current measurement that the superposition of all parasitic magnetic fields is precisely not oriented in the sensitivity direction, i.e. they pass normally through a magnetic-field-neutral orientation plane and thus can cause little or no change in the sensor value. As a result, only magnetic fields generated by a conductor section active in current measurement, in particular by one or both legs of a U-shaped conductor element, cause a change in the sensor value.

In an advantageous embodiment, the at least one magnetic-field-sensitive sensor element is arranged at an inclination to the conductor element assigned to the sensor element. This makes use of the fact that the magnetic-field-sensitive structures of the sensor element are only sensitive to magnetic fields in one or two spatial directions, i.e. magnetic fields perpendicular to these preferred magnetic field directions are not detected by the magnetic-field-sensitive structures.

Magnetoresistive sensor elements are advantageously employed as magnetic-field-sensitive sensor elements, operating for example according to the AMR effect (anisotropic magnetic resistance), the GMR effect (giant magnetic resistance) or the TMR effect (tunnel magnetic resistance). Sensor elements that utilize the Hall effect can equally be used. As a rule, AMR, TMR and GMR sensors have a sensitivity direction which lies in the plane of the sensor structure, as a rule in the chip plane, in most cases at right angles to a current direction through the sensor structures, and at right angles to the normal of the arrangement plane of the sensor structures. In most cases, Hall-based sensors have a sensitivity direction perpendicular to the arrangement plane of the sensor structure.

The at least one sensor element can advantageously be inclined relative to the U-shaped conductor element in such a way that the effect of the magnetic field that is generated by the currents in the connecting bridge between the two legs of the U-shaped conductor element is minimized. This is advantageously achieved in that the at least one sensor element is positioned such that the components of the magnetic field lying in the sensitivity direction of the sensor element and generated by currents in the connecting bridge between the two legs of the U-shaped conductor section are minimized at the location of the sensor element. AMR sensor elements made using thin-film technology according to the prior art are, for example, insensitive to magnetic field components that impact the sensor plane perpendicularly. In an exemplary embodiment of this type, the angle of inclination is selected such that interfering magnetic fields will impact the at least one AMR sensor element perpendicularly. If the position or distance of the sensor element relative to the U-shaped conductor element is changed, the optimum angle of inclination must also be adjusted such that the interfering magnetic fields again do not have any components in the sensitivity direction of the sensor element. Since the distance of the sensor element also changes the resulting measurement sensitivity of the arrangement, an optimization of the position and the optimum angle of inclination can be made on the basis of the requirements for sensitivity, any necessary insulation spacing, and the resulting dimensions of the arrangement. The magnitude of the angle of inclination α is advantageously in the range 0<|α|<120°. A further enlargement of the angle of inclination would lead to an enlargement of the resulting dimensions beyond the extent of the conductor element, which is precisely what has to be avoided in many applications.

In addition to the magnetic field generated by currents in the connecting bridge between the two legs of the U-shaped conductor element, the magnetic fields generated by currents through the connecting lines to the U-shaped conductor element can also negatively influence the measuring precision. The angle of inclination can therefore be particularly advantageously selected in a further exemplary embodiment such that the superposition of the magnetic fields of the connecting bridge and the connecting lines at the location of the sensor element only yield minimal components in the sensitivity direction of the sensor element.

In a further advantageous exemplary embodiment, the at least one sensor element can be a gradient sensor, so that the arrangement is largely insensitive to external, homogeneous interfering magnetic fields. It is however also possible for a plurality of sensor elements, each measuring the absolute field, to be provided, where additional evaluation electronics combine the output signals of the sensor elements in an appropriate manner. By arranging a large number of sensor elements measuring the absolute field, it is in particular possible to achieve an optimum suppression of interference effects. The optimum angle of inclination for different sensor elements can also differ here.

The U-shaped conductor element of the arrangement can particularly advantageously be formed in that appropriate slots are made in a flat and straight section of conductor. Straight conductors with a U-shaped partial structure of this type have advantages in respect of their dimensions and the simplicity of their manufacture.

To permit a compact, space-saving variant and the arrangement of the sensor elements with two magnetic-field-sensitive sensor units, in particular magnetic-field-sensitive resistors, which can be connected in a Wheatstone measuring bridge, on a common base plate, in particular on a chip substrate or PCB, it is advantageous for both legs of the U-shaped conductor element to be arranged parallel and at a short distance to each other. In this way, magnetic-field-sensitive sensor units can be arranged in one compact component whose footprint at least partially covers both legs. A component of this type can be fastened to both legs simultaneously by a fastening means such as an engaging or snap-fit element. A compact sensor element of this type that covers both legs of the U-shaped conductor element can be manufactured economically and mounted easily, where the total size of the arrangement for measuring the magnetic fields has small dimensions. In a further advantageous embodiment, a fastening means can be provided on which the at least one sensor element is mounted, and hence the at least one sensor element is fixed at an inclined, turned and/or vertically displaced position relative to the associated conductor element. The fastening means can in particular be designed such that, to simplify assembly and comply with the permitted tolerances, it engages onto or into the conductor element, or is equipped with modified mounting or adjustment aids permitting exact positioning on the associated conductor element. Guide grooves or adjusting pins, for example, can be provided to permit precise mounting relative to the current sensor element. The fastening means is advantageously made of a plastic or comprises elements that consist of a plastic. This allows the fastening means to be attached to the conductor element without the use of tools, and also to be released again in the event of a defect.

The fastening means can moreover have at least one electrically conductive track which contacts the at least one sensor element. Additional wiring effort is thus avoided, since the conductive track is already included in the fastening means. The conductive tracks can here be laid in a defined manner, and can be arranged such that their magnetic fields do not have any parasitic influence on the magnetic field measurement, or that their parasitic magnetic fields mutually compensate. Supply lines can thus be routed in the fastening means according to a twisted-pair principle. Novel technologies, the so-called MID technology (MID=Moulded Interconnect Devices), allow a plastic element to be given additional conductive tracks that permit an electrical contact to be made with electrical components that are mounted on the plastic. In a further exemplary embodiment, the fastening means therefore has additional conductive tracks with which the at least one sensor element is contacted. The at least one sensor element can here, for example, be contacted by means of bonding technology or by a soldered connection to the conductive tracks of the fastening means.

In a further advantageous embodiment, the arrangement can have additional components which are, for example, necessary for the provision of the sensor signals. These additional components too can be mounted on the fastening means, where the electrical connection is made between the components and at least one sensor element, for example, by means of MID technology or a bonding technology.

One advantageous arrangement can also comprise additional connecting elements, for example a plug-in connector, with which electrical contact can be made to the sensor arrangement. This plug-in connector can in a further embodiment be mounted on the fastening means. Making the electrical connection to components that may be present and/or to the at least one sensor element can be done in a manner similar to that described above, for example by bonding or soldering.

It is however also possible for an additional circuit carrier to be provided that receives one or more of the components mentioned above, makes any electrical connections that may be required between the components, and is mounted as one unit on the fastening means. Further embodiments in which components are partially mounted directly on the fastening means and additional circuit carriers are provided mounted on the fastening means, are also conceivable.

To protect against mechanical influences, for example against soiling or moisture, or to avoid non-permissible mechanical stress, the elements of the sensor arrangement can be sheathed in a further advantageous embodiment. A sheath that simultaneously encloses the associated electrical conductors is advantageous. The contacts of a plug-in connector that may be provided for making contact with the unit can here be in a recess of the sheath.

According to one advantageous embodiment, the three-dimensional spatial arrangement of the sensor element and the conductor section parasitic to current measurement can be arranged relative to one another in such a way that a magnetic-field-neutral orientation plane of the sensor element whose normal is oriented at right angles to the sensitivity direction, is oriented perpendicular to a tangent of a closed magnetic field line of the parasitic magnetic field generated by the current distribution of the conductor section parasitic to current measurement. In other words, this embodiment proposes that the magnetic-field-neutral orientation plane, in many cases the plane in which the sensor structures of the sensor element are embedded, be positioned at a height and at an angle of orientation such that parasitic magnetic fields penetrate this plane at right angles. In this way parasitic magnetic fields do not have components that lie inside the magnetic-field-neutral orientation plane, in particular in the sensitivity direction, so that these neither impair a sensor sensitivity, for example by interfering with an internal magnetization of the sensor structures, nor do they constitute components in the magnetic-field-sensitive sensitivity direction.

Preferably the conductor element can be a punched and bent metallic component, and the centre of gravity of the current density distribution through the conductor section parasitic to current measurement and a magnetic-field-neutral orientation plane, whose normal is perpendicular to the sensitivity direction can be substantially at the same vertical level z at the location of the sensor element. Alternatively or in combination, the sensor element can be arranged on a curved conductor section that is active in current measurement, whereby the conductor section parasitic to current measurement and a magnetic-field-neutral orientation plane whose normal is perpendicular to the sensitivity direction are substantially at the same vertical level z at the location of the sensor element. The above-mentioned variants for the creation of a height difference between conductor sections parastic to current measurement of a connecting bridge and conductor sections active in current measurement of a leg of a U-shaped conductor element have the effect that a magnetic-field-neutral orientation plane is arranged at about the height of a concentrated line current that flows in the conductor section parasitic to current measurement. The supply line current thus in effect lies in the same plane as the magnetic-field-neutral orientation plane, so that the parasitic magnetic fields penetrate this orientation plane substantially at right angles and do not have any disadvantageous effect on the magnetic field measurement. The magnetic-field-sensitive orientation plane is thus only penetrated by magnetic fields from the conductor section active in current measurement of the leg, which is in the z-plane displaced relative to the plane of the supply line current and to the magnetic-field-neutral orientation plane of the sensor element.

In a further embodiment, a vertically displaced arrangement of conductor sections active in current measurement and parasitic to current measurement is proposed on or in a PCB structure, in particular a multi-layer PCB (printed circuit board) on different layers. For this purpose, the sensor element can advantageously be arranged on a layer of the multi-layer PCB, preferably on the same layer as the conductor sections parasitic to current measurement. The conductor structures that define the conductor sections parasitic to current measurement, in particular current supply lines and current discharge lines, as well as the connecting bridge between two conductive legs, can be arranged on a first metallization plane of a multi-layer PCB, where the sensor element can also be arranged on this plane. The current-measurement-sensitive conductor sections, in particular the legs of a U-shaped conductor structure, can be arranged on another vertically displaced plane as a further metallization layer. The conductor sections of the planes can be joined by vias or by through-contacts. Further components, compensation magnets or compensation magnetic field coils and/or electronic components can be arranged on the PCB structure. In particular, evaluation and/or display elements and/or connecting interfaces, i.e. plug/coupling elements can be arranged on the PCB in order to provide a compact component. The manufacture of the PCB layers can be done using usual PCB production methods, so that an economic manufacture with a high manufacturing precision can be achieved. The PCB structure reinforces the current measuring arrangement, so that said structure is constructed as a stable component.

### BRIEF DESCRIPTION OF THE DRAWINGS

Further advantages, characteristics and details of the invention emerge from the following exemplary embodiments described as well as with reference to the drawings. In detail, the drawings show:

FIG. 1: arrangement with U-shaped conductor according to the prior art;

FIG. 2: representation of the magnetic field directions of a U-shaped conductor through which current is flowing according to the prior art;

FIG. 3 representation of the magnetic field lines of a U-shaped conductor through which current is flowing with a shortened leg length;

FIG. 4 schematic diagram of a sensor element with one magnetic-field-sensitive orientation plane and two magnetic-field-neutral orientation planes;

FIG. 5 representation of the resultant magnetic field vectors and the magnetic field lines when an auxiliary field is present;

FIG. 6 arrangement of a gradient sensor with a straight electrical conductor element;

FIG. 7 sectional view corresponding to FIG. 6 with a representation of an optimum angle of inclination;

FIG. 8 exemplary embodiment in accordance with an aspect of the invention with a fastening means mounted on the electrical conductor;

FIG. 9 sectional view of embodiments of sensor arrangements with different three-dimensional arrangements of conductor sections active in current measurement relative to those parasitic to current measurement;

FIG. 10 embodiment of a sensor arrangement with an electrical conductor as a punched and bent component;

FIG. 11 further exemplary embodiment with additionally mounted components;

FIG. 12 further exemplary embodiment of an electrical conductor with sheath;

FIG. 13 exemplary embodiment of the sensor arrangement with a plurality of sensor elements;

FIG. 14 exemplary embodiment of a sensor arrangement with a plurality of sensor elements inclined at an angle α.

### DETAILED DESCRIPTION

The same reference characters have been used to identify components that are identical or of similar type in the figures. The figures shown are not to scale and serve only to represent the various sensor arrangements schematically and in principle.

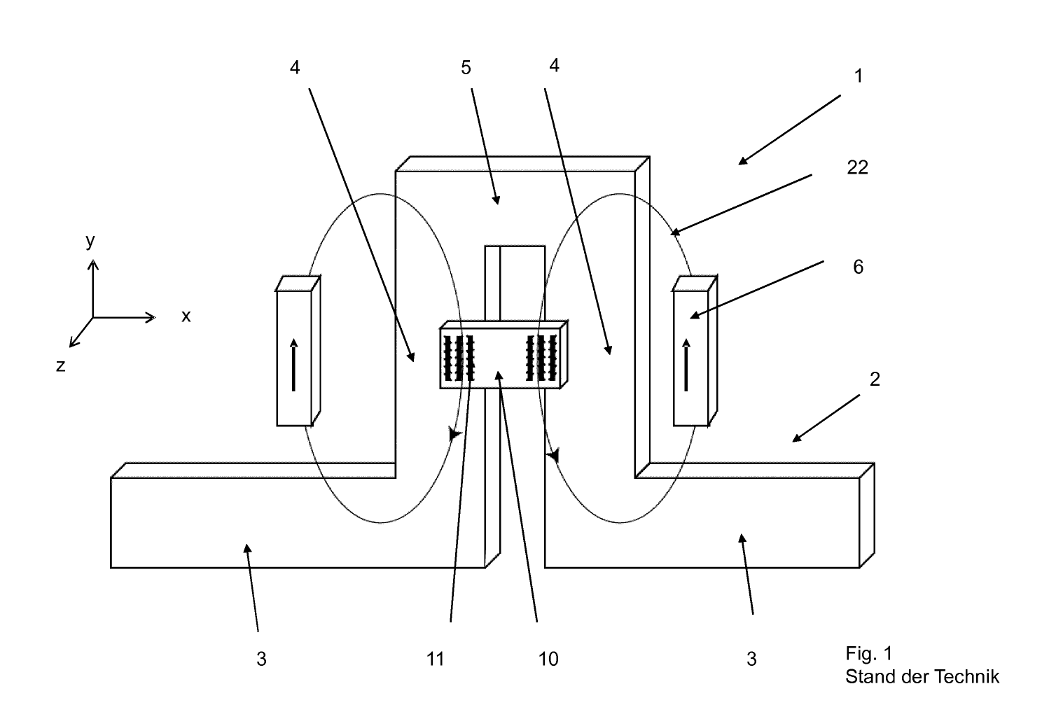

FIG. 1 shows an arrangement for measuring electrical currents according to the prior art. The arrangement 1 consists of an electrical conductor 2 lying in the x-y plane which has the connecting lines 3, the leg 4 and the connecting bridge 5, as well as of a sensor element 10 that is arranged in a plane parallel to the electrical conductor 2. The sensor element 10 here has two sensor structures 11 located at a distance from one another, permitting a measurement of the gradient magnetic field generated by a current in the U-shaped conductor 2. In order to stabilize the sensor structures in 11, the arrangement has two permanent magnets 6 which generate an auxiliary magnetic field 22 in the region of the sensor structures 11. The sensor structures can for example contain magnetoresistive resistor elements whose electrical resistance changes depending on the magnetic field components lying in the x-y plane.

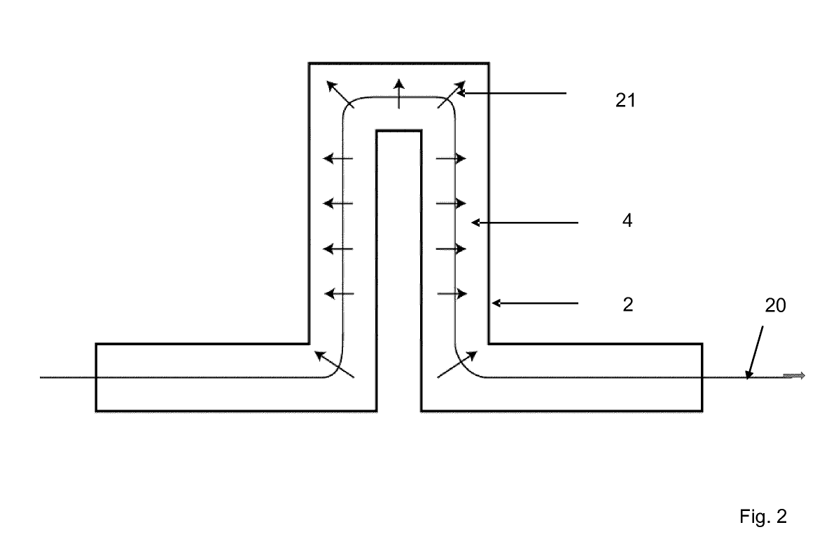

FIG. 2 indicates a current 20 flowing in the U-shaped conductor element 2, and so generating a magnetic field corresponding to the directions of the arrows 21 shown on the surface of the electrical conductor. It can clearly be seen that the directions of the magnetic fields in the region of the leg 4 each have opposing directions, so that according to the prior art a gradient measurement by means of a suitable sensor element 10 is possible in this region.

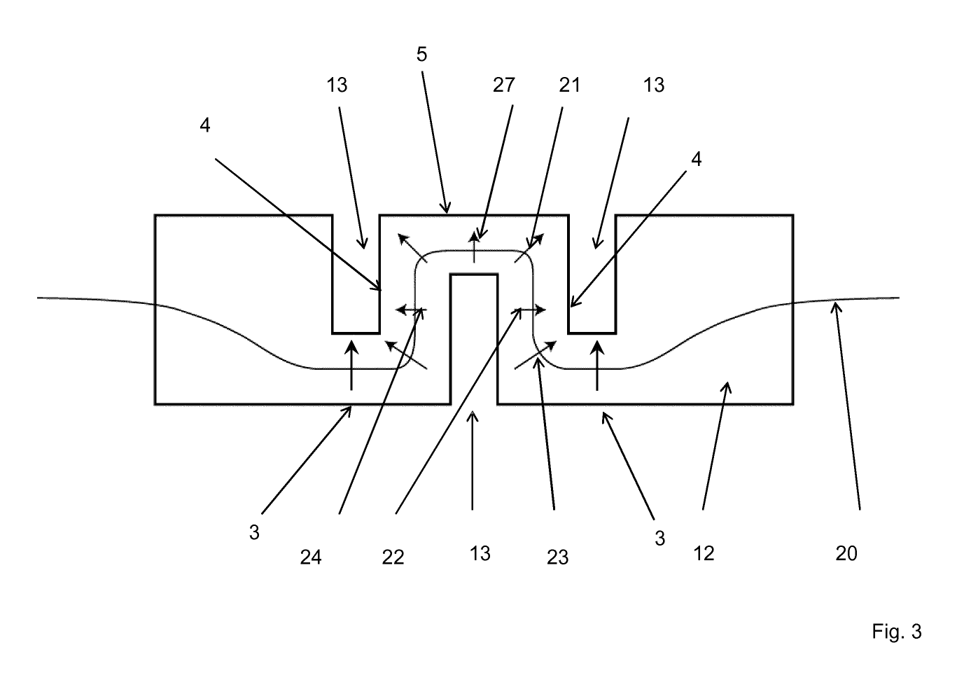

FIG. 3 shows a straight electrical conductor 12 in which a U-shaped partial structure 2 is formed by the introduction of slots 13. Corresponding to FIG. 2 a current 20 is indicated which generates a resultant magnetic field with the exemplary field lines 21, 22, 23, 24. It can clearly be discerned that in the region of the leg 4, magnetic field gradients are again generated, where, due to the spatial proximity, an influence from the magnetic fields is to be expected, e.g. with the field vectors 21 and 23. In addition, in particular in the region of the connecting bridge 5 and the connecting lines 3, magnetic fields are generated whose field direction is at right angles to the magnetic fields 22 and 24 in the region of the leg 4. In particular, magnetic fields from the connecting bridge 5 have a parasitic effect on the characteristic sensor value.

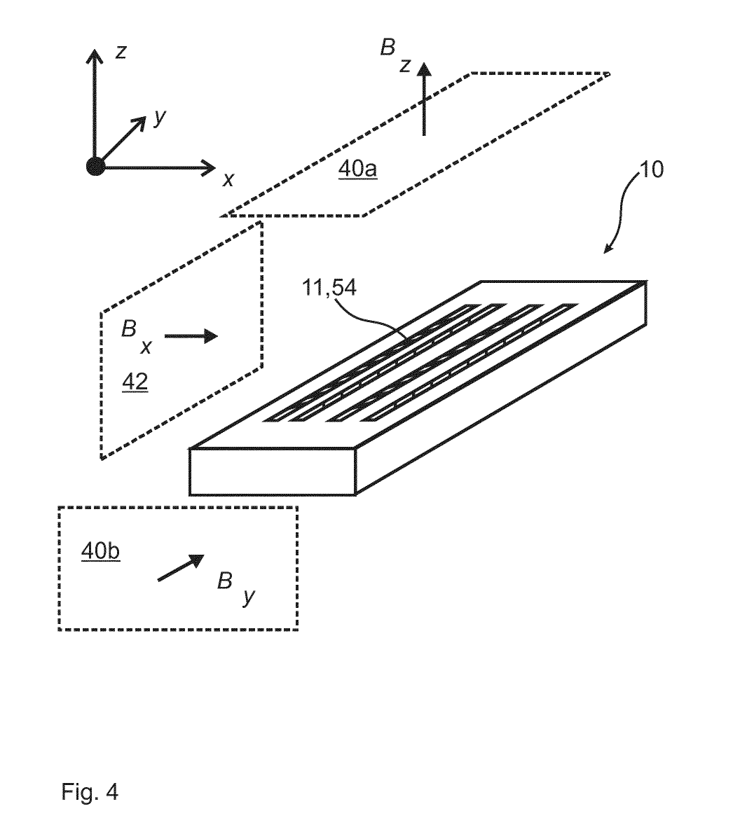

FIG. 4 shows a schematic perspective view of a sensor element 10 with four sensor structures 11 which are formed as magnetoresistive AMR resistor strips 54 (anisotropic magnetoresistive resistor strips). The resistor strips can preferably be connected in a Wheatstone measuring bridge as the resistor of one or two partial branches. The position and orientation of the resistor strips 54 define two magnetic-field-neutral orientation planes 40a and 40b on the surface of a substrate, and for the sake of clarity are sketched displaced relative to the plane of the resistor strips 54, but which are however allocated in this plane. Magnetic field vectors By and Bz, which are oriented perpendicularly to these planes 40a, 40b, i.e. penetrate these planes in the normal direction, have at least up to a maximum magnetic field strength no significant effect on a change in the resistance of the resistor strips 54. Magnetic field components which penetrate the plane 40a thus do not affect the sensor value. Magnetic field components that penetrate the plane 40b can change, lower or disturb the magnetic field sensitivity of the resistor strips 54 and are therefore to be avoided. The behaviour is different for a magnetic field vector component Bx, which is perpendicular to the magnetic-field-sensitive orientation plane 42 in a sensitivity direction 70, and whose magnitude has a significant effect on a change in the resistance of the resistor strips 54. The following is achieved by a three-dimensional orientation of the plane receiving the sensor structure 11 relative to the electrical conductor 12: the magnetic fields parasitic to current measurement that are caused by the connecting bridge 5 and the current-carrying connecting lines 3 as well as by the supply lines to the sensor element 10, pass, at the location of the sensor structures, perpendicularly through the magnetic-field-neutral orientation planes 40a, 40b, in particular the orientation plane 40a. The orientation plane 40a covers the same area as the arrangement plane of the sensor structures 11. The interfering influence of parasitic magnetic fields can in this way be effectively suppressed, and the sensor value is primarily or exclusively influenced by the magnetic fields of the conductor sections 30 active in current measurement. For the orientation, an attempt is also made to arrange that the magnetic fields generated by the conductor section 30 active in current measurement, in particular by the leg 4 of the U-shaped electrical conductor element 2, penetrate the magnetic-field-sensitive orientation plane 42 preferably perpendicularly.

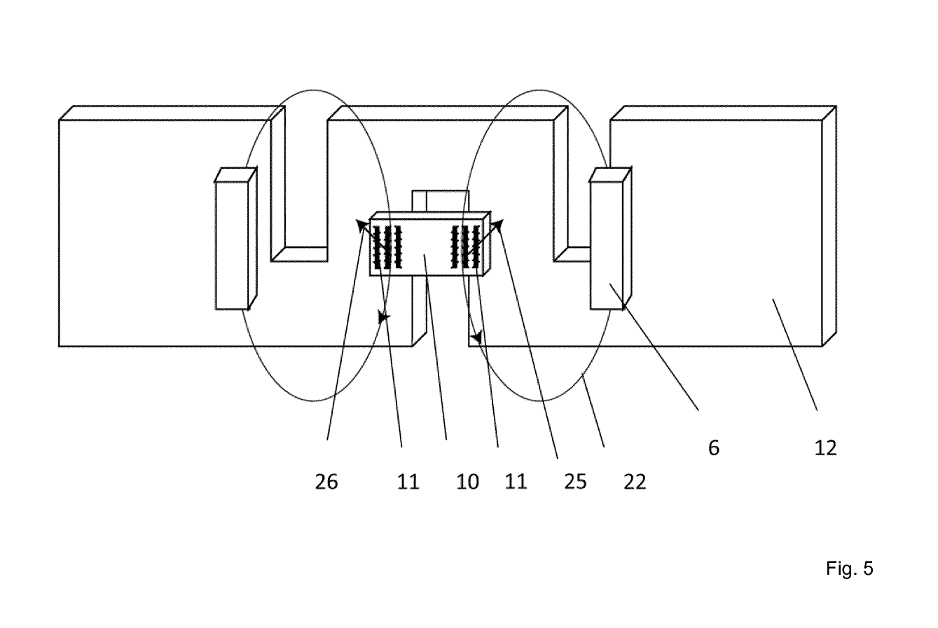

FIG. 5 shows which resultant magnetic fields 25, 26 arise at the location of the sensor structures 11 when the various magnetic fields illustrated in FIG. 3 are superposed at the location of the sensor. It can clearly be discerned that the magnetic fields 25 and 26 have components that also weaken the auxiliary magnetic field generated by the permanent magnets 6 at the location of the sensor structures 11. As the magnitude of the current rises, this can lead to incorrect measurements and, in some cases, to demagnetization processes at the location of the sensor structures 11.

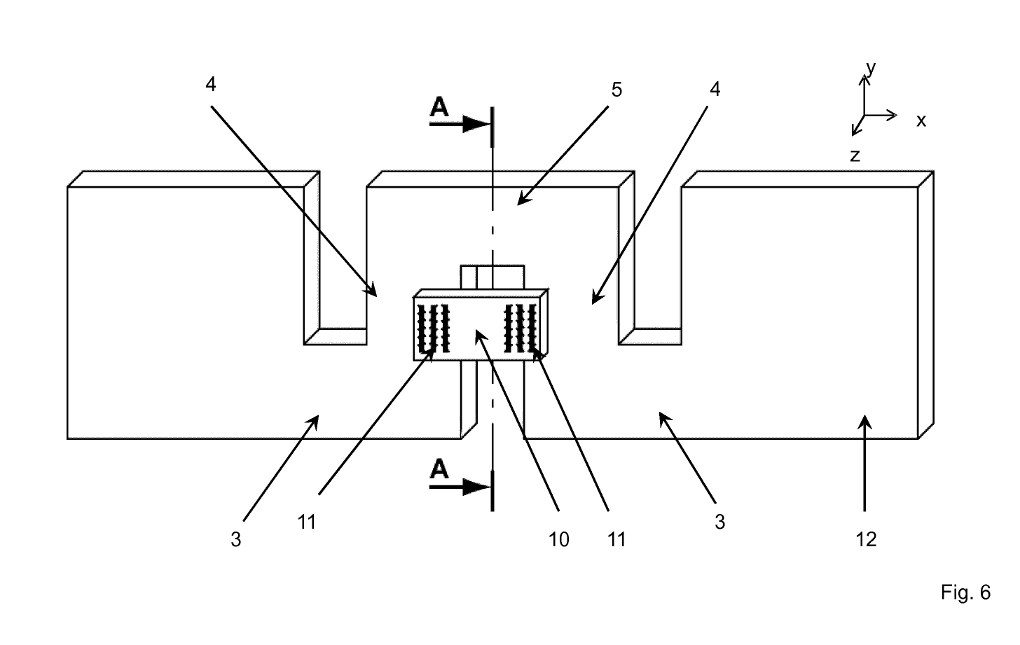

FIG. 6 shows an arrangement consisting of a straight electrical conductor 12 which comprises a partial structure consisting of connecting lines 3, the legs 4 and a connecting bridge 5. A sensor element 10 with the sensor structures 11 is arranged above the electrical conductor 12.

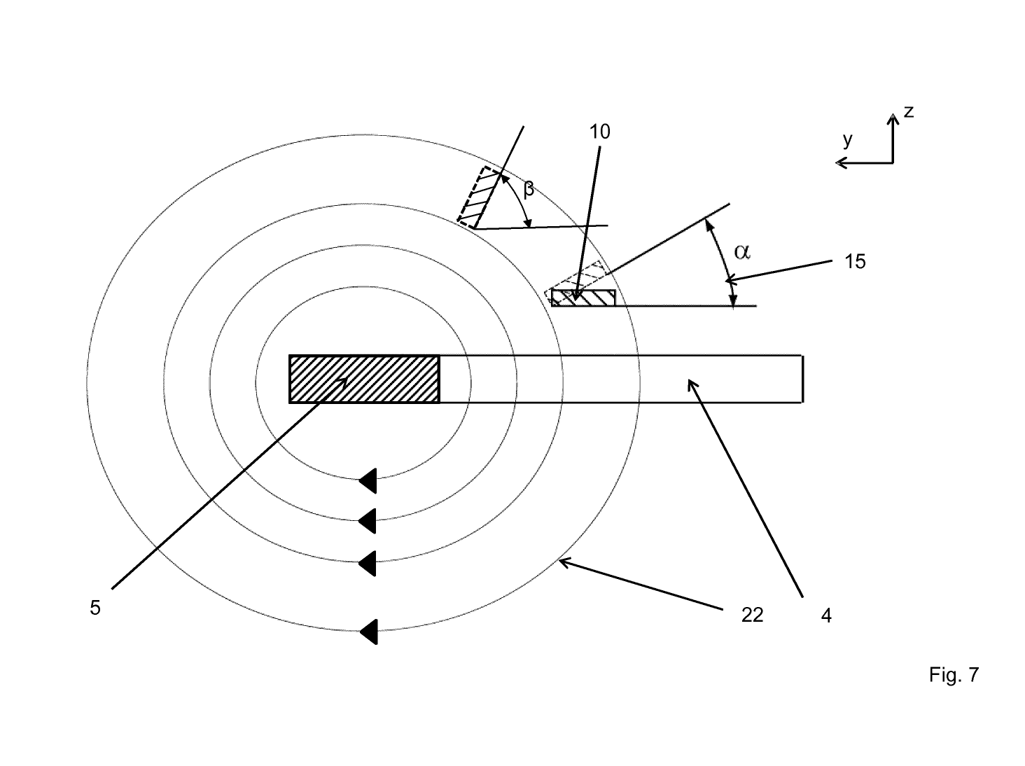

FIG. 7 shows, in a sectional view that is not to scale along the line A-A of FIG. 6, parasitic magnetic field lines 22 which are generated by a flow of current in the connecting bridge 5. The sensor element 10 is located above the leg 4 of the U-shaped conductor element. If the sensor element 10 is, for example as a result of requirements for insulation strength, mounted at a distance from the electrical conductor 12 and parallel to the plane of the electrical conductor 12, then the field lines 22 do not penetrate the sensor element 10 perpendicularly. There are thus magnetic field components in the plane of the sensor element 10 that falsify the measurement signal of a sensor element 10 sensitive in the plane. Due to an inclined position of the sensor element 10 in accordance with an aspect of the invention by an angle α 15 relative to the plane of the electrical conductor 12, it can be achieved that the magnetic field lines 22 impact the sensor element 10 perpendicularly. If the sensor element 10 has sensor structures that are insensitive to magnetic fields impacting perpendicularly, then magnetic fields caused by currents in the connecting bridge 5 and in the connecting lines 3 no longer have an interfering effect. If the position of the sensor element 10 is changed, e.g. along the closed magnetic field lines, then in accordance with an aspect the invention a rising angle of inclination is also associated with an increase in the distance to the legs 4 of the U-shaped conductor element 2. For the purposes of explanation, FIG. 7 shows a further position with the associated optimum angle of inclination β, but with an enlarged distance to the electrical conductor 12. A further turning of the sensor element 10 along the magnetic field lines is possible, where the sensitivity of the arrangement 1 changes correspondingly as a result of the change in the distance. It can be easily discerned from FIG. 7 that an arrangement inverted relative to the plane of the electrical conductor, i.e. sensor element 10 underneath the electrical conductor 10 and with a negative angle of inclination, will be equally advantageous.

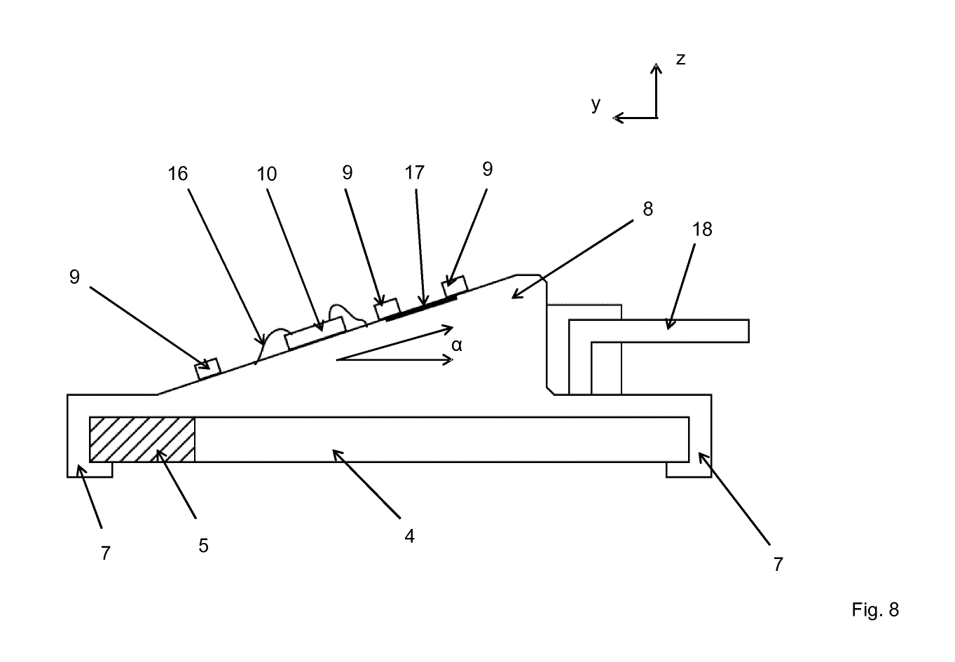

FIG. 8 shows schematically a fastening means 8 that receives the sensor element 10 and fixes it in an inclined position in relation to the conductor element 4 illustrated in FIGS. 5 and 6. Additional components 9 can be mounted on the fastening means 8. For the electrical connection of the components, bonding wires 16 and conductive tracks 17 are shown by way of example. The fastening means 8 is designed in such a way that it engages onto the specified structure of the electrical conductor 12. For this purpose, engaging hooks 7 for example are provided which partially enclose the electrical conductor at 12 after the fastening means 8 has been mounted. The fastening means 8 can preferably consist of a plastic. Additional plug-in connectors 18 can be connected to the fastening element 8 and can enable electrical contact (not shown in detail) of the component 9 and the sensor element 10. Alternatively the components 9 and the sensor element 10 can also first be mounted on a circuit board which is then mounted on the fastening means 8. The angle of inclination 0 of the fastening element 8 illustrated can be further optimized. It is conceivable, alternatively or additionally, to provide at least partially magnetically anisotropic material in the fastening means 8 or in a circuit board mounted thereon, or to arrange in the immediate vicinity of the sensor element 10 a magnetically anisotropic material having a permeability tensor which affects the path of the parasitic magnetic field in the direction of the normal to a magnetic-field-neutral orientation plane 40. Thus, for example, necessary mechanical specifications can be satisfied, and the sensitivity of the sensor arrangement further improved, since the parasitic magnetic fields along a field line curve defined by the permittivity-tensor material are advantageously guided away from a sensitivity direction.

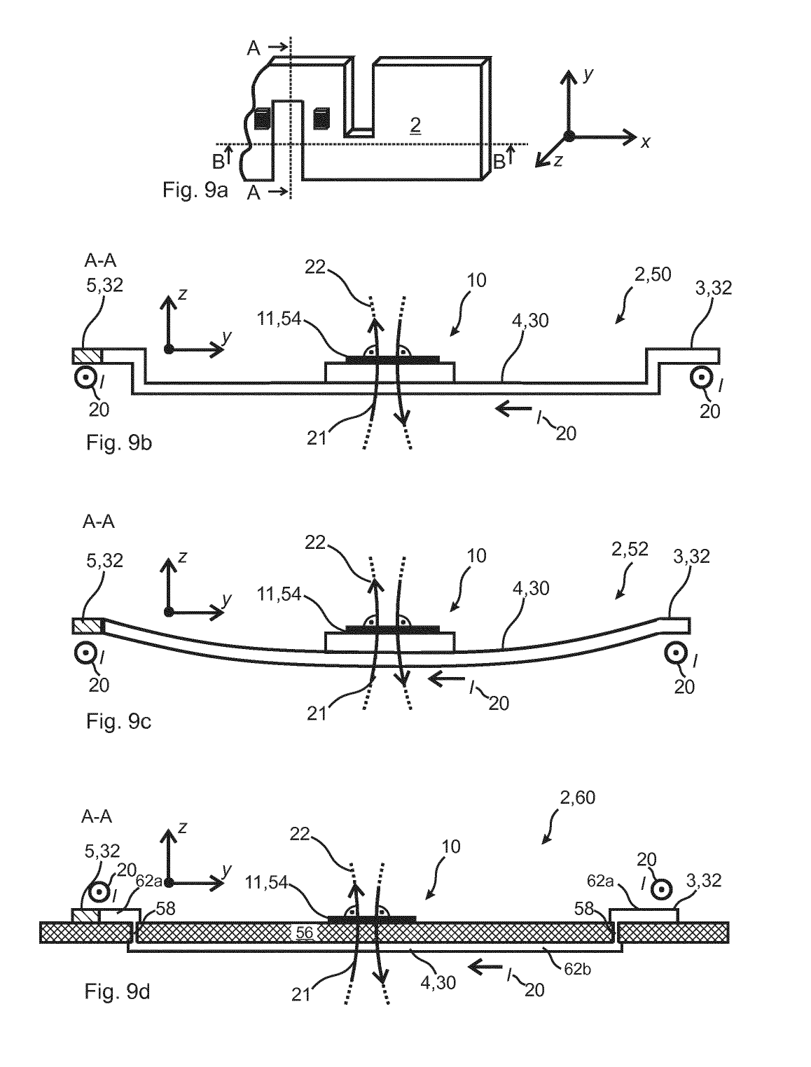

FIG. 9 illustrates schematic sectional views, not to scale, of a plurality of embodiments of a sensor arrangement with various three-dimensional arrangements of conductor sections active in current measurement in respect of sections parasitic to current measurement. For this purpose, FIG. 9a shows schematically a sectional line A-A through a U-shaped electrical conductor element 2 of an electrical conductor 10, as has already been shown in FIG. 6, and which defines the sectional views of FIGS. 9b to 9d. A further sectional line B-B defines the viewing plane of FIG. 9e.

FIG. 9b shows a first embodiment of the U-shaped electrical conductor element 2 as a punched and bent part 50 in which a leg 4 as a conductor section 30 active in current measurement is arranged in a lower z-plane in the y-direction, and the connecting bridge 5 and the connecting lines 3 as conductor sections 32 that are parasitic to current measurement are oriented in the x-direction on an upper z-plane. The direction of current flow 20 of a current I to be measured is illustrated schematically. A sensor element 10 is arranged in the central region of the leg 4 and comprises sensor structures 11 that are, for example, designed as resistor strips 54 that are also oriented in the y-direction, and whose magnetic-field-neutral orientation plane is located in the y/z plane and is penetrated by magnetic field components oriented in the x-direction of the current I flowing in the y-direction through the legs 4, 30. Magnetic vector components of the connecting bridge 5 and the connecting lines 3 as conductor sections 32 parasitic to current measurement are illustrated by dashed lines. Due to the arrangement of the conductor section 30 active in current measurement on a lower z-plane, and the conductor section 32 parasitic to current measurement on an upper z-plane, where on the upper z-plane the magnetic-field-neutral orientation plane 40a also lies on the x/y plane (cf. FIG. 4), the parasitic magnetic field components penetrate the plane 40a at right angles and have no effect on a change in the sensor value of the sensor element 10. The vertical z-displacement between the conductor section 30 active in current measurement and the conductor sections 32 parasitic to current measurement is selected such that the centre of gravity of the current density distribution of the current 20 to be measured through the conductor section 32 parasitic to current measurement, which corresponds to a line current, is on the same vertical z-plane as the magnetic-field-neutral orientation plane 40a, so that passage of the parasitic magnetic field components at right angles through the plane 40a is ensured.

FIG. 9c illustrates a similar configuration to that of FIG. 9b as a section A-A, however the U-shaped electrical conductor element 2 is designed as a gradually curved conductor section 52 with a large radius of curvature, and not as a punched and bent part 50 with small radii of curvature. The design of the leg 4, 30 active in current measurement as a curved conductor section 52 has the advantage that manufacturing tolerances can be averaged out, or that a slightly different radius of curvature only has a minor effect on the right-angled penetration as discussed above through the magnetic-field-neutral orientation plane 40a. The electrical conductor elements can therefore be manufactured with a greater error tolerance, or can be aligned subsequently.

FIG. 9d shows a configuration comparable to that of FIG. 9b as the section A-A, but in this case the U-shaped electrical conductor element 2 is not a punched and bent part 50, but is a PCB (printed circuit board) arrangement 60 or is a chip substrate arrangement in which on the plane of a lower layer or underneath a substrate layer 56 the conductor leg section 4, 30 active in current measurement, is arranged as a lower metallization layer 62b, and the connecting bridge and connecting conductor sections 3, 5, 32 parasitic to current measurement are arranged on the plane of an upper layer or on the substrate layer 56 as an upper metallization layer 62a. The conductor sections 3, 4 and 5 are connected to one another by vias 58. The sensor structures 11 of the sensor element are applied to the substrate surface 56, so that the parasitic magnetic field components penetrate the sensor structures in 11 perpendicularly to the substrate surface.

FIG. 9e shows a further three-dimensional U-shaped electrical conductor element 2 viewed in the Z-direction inside a PCB arrangement 60. The PCB arrangement 60 is a multi-layer PCB 64 with a plurality of layers 56a to 56c. A metallization layer 62a is applied to the plane of the upper layer 56c, and forms the connecting bridge 5 and the connecting lines 3 of the U-shaped conductor element 2, and represent conductor sections 32 parasitic to current measurement. In a layer plane 56b vertically displaced in the z direction, conductor sections 30 active in current measurement are formed as legs 4 in a metallization layer 62b. The metallization layers 62a, 62b are electrically connected to one another by means of vias 58, i.e. through-contacts through the PCB substrate layer 56c. A sensor element 10 comprising sensor structures 11 in the form of magnetic-field-sensitive resistor strips 54 on a magnetic-field-neutral orientation plane 40a is arranged on the layer 56c in the region of the leg 4. The magnetic-field-neutral orientation plane 40a is arranged at a height z that corresponds to the z-height and orientation of a concentrated linear current I 20 which flows in a distributed manner through the conductor sections 32 parasitic to current measurement. Parasitic magnetic fields which, as illustrated in FIG. 7, usually constitute concentric circles 22 surrounding the conductor sections 32 parasitic to current measurement, thus penetrate the magnetic-field-neutral orientation plane 40a normally to the plane 40a. The sensor structure 11 has a sensitivity direction 70 that points in the x-direction, thus lying within the orientation plane 40a and at right angles to the orientation of the parasitic magnetic fields 22. This sensor arrangement is based, like the arrangements shown in FIGS. 9b to 9d, on a spatially displaced arrangement of the sensor element 10, so that parasitic magnetic fields do not penetrate it in the sensitivity direction, but in particular at right angles to the sensitivity direction of the sensor element.

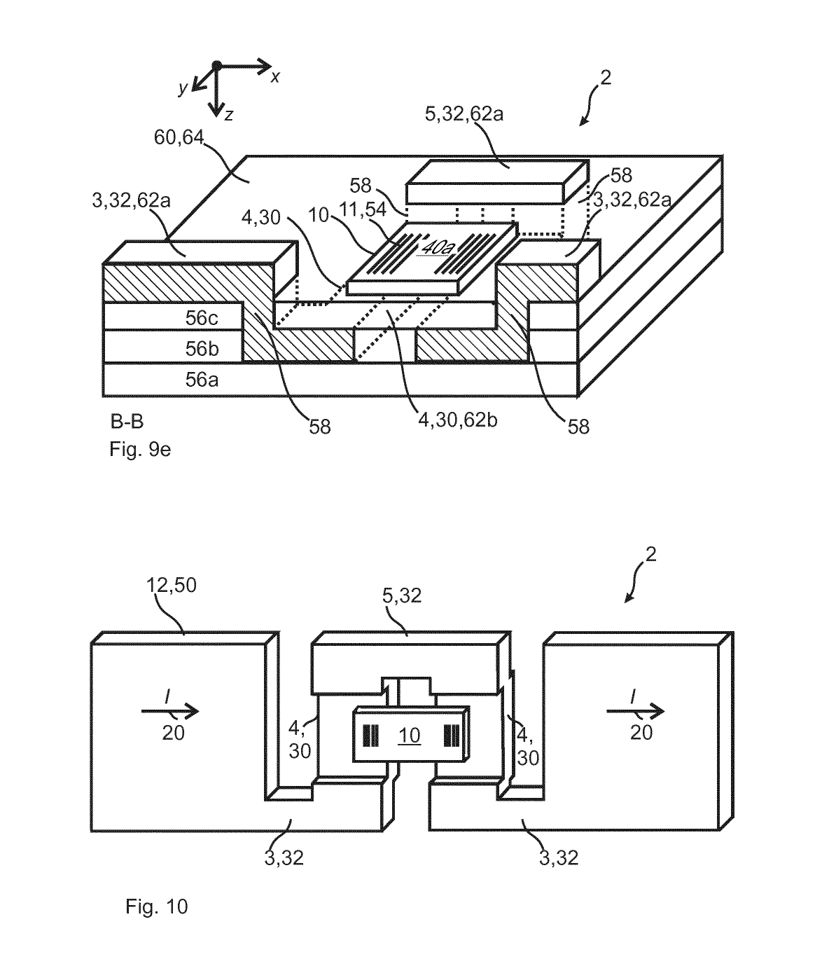

FIG. 10 shows, corresponding to the sectional view embodiment of FIG. 9b, a U-shaped current conductor element 2 as a punched and bent part 50, in which the leg 4, 30 active in current measurement is set back in a z-direction relative to the leg and connecting conductor sections 3, 5, 32 parasitic to current measurement, so that parasitic magnetic field components pass substantially at right angles through a magnetic-field-neutral orientation plane 40a—see FIG. 4, arranged on the sensor structures 11 of the sensor element 10. By the arrangement of the leg 4 displaced in the z-direction relative to the connecting lines 3 and the connecting bridge 5, it is assured that parasitic magnetic field components only penetrate the magnetic-field-neutral orientation plane 40a, whereas the magnetic field components active in current measurement that are to be detected penetrate the magnetic-field-sensitive orientation plane 42 of the sensor element 10.

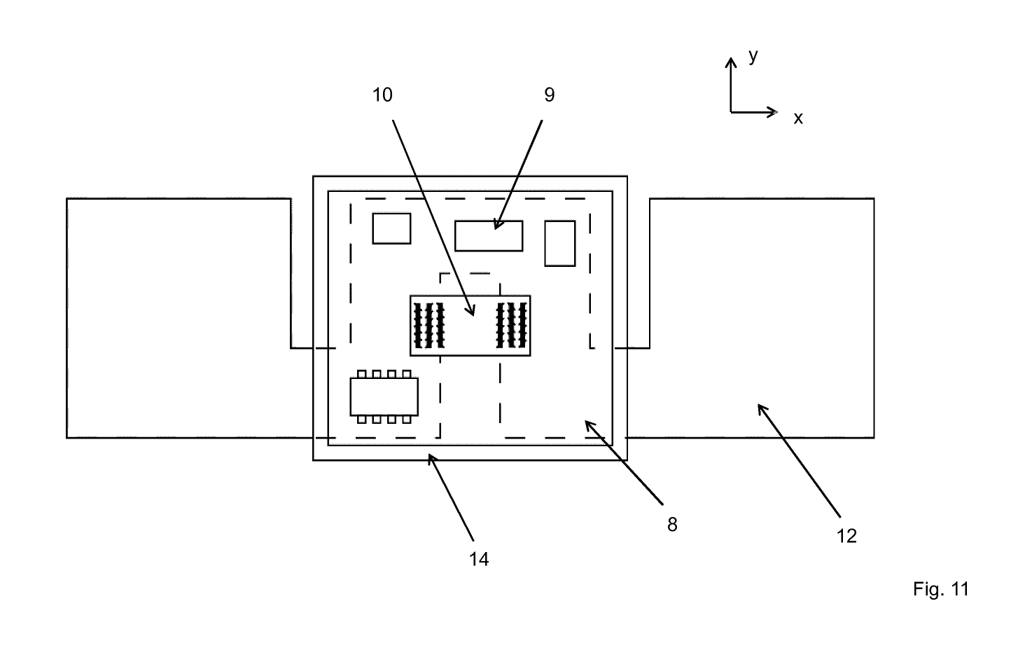

FIG. 11 illustrates a further advantageous exemplary embodiment with a straight electrical conductor 12 viewed from above, in which the fastening means 8 is shown with the associated components of sensor element 10 and components 9, and is then protected by a sheath 14 against mechanical influences from outside.

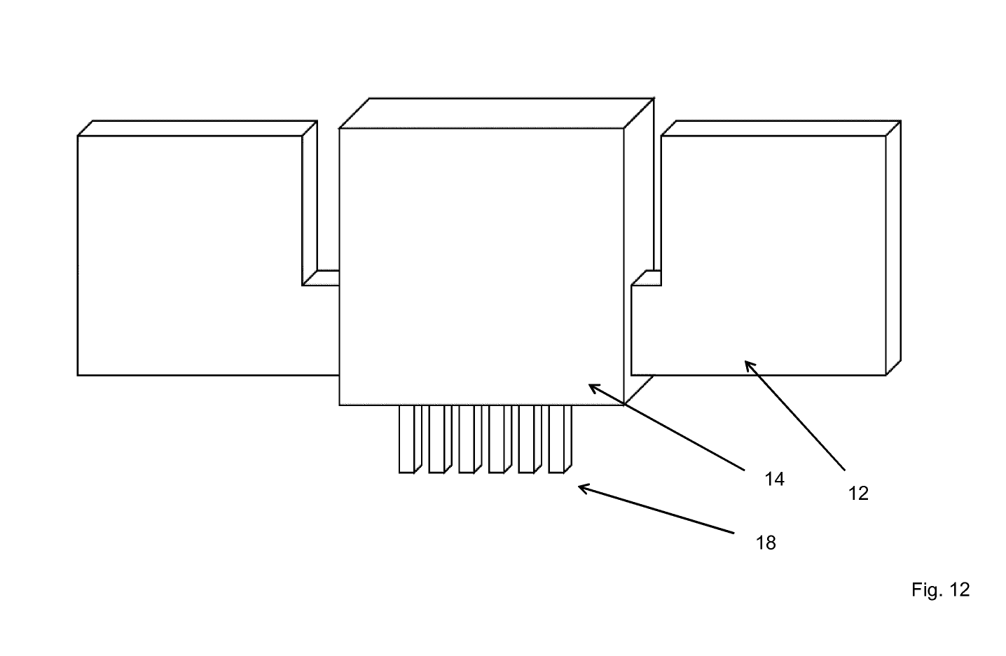

FIG. 12 shows a further advantageous exemplary embodiment in which the (no longer visible) fastening means 8 is protected by a sheath 14, where the sheath 14 simultaneously forms one unit with the straight electrical conductor 12. The contact with the at least one sensor element 10 and with any components 9 that may be present is established by the illustrated contacts of a plug-in connector 18 which otherwise is enclosed by the sheath 14.

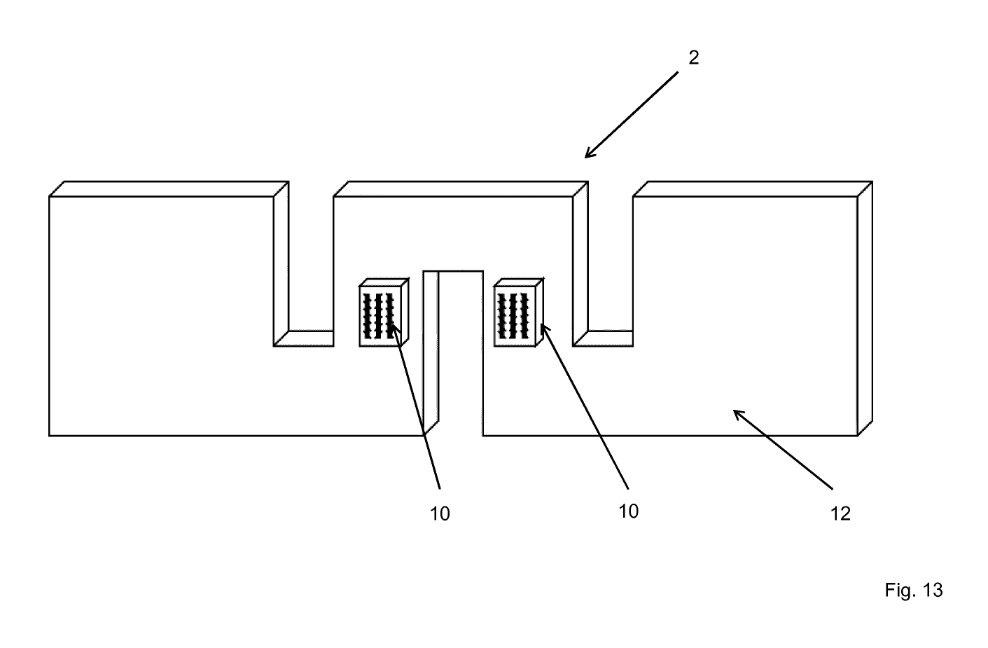

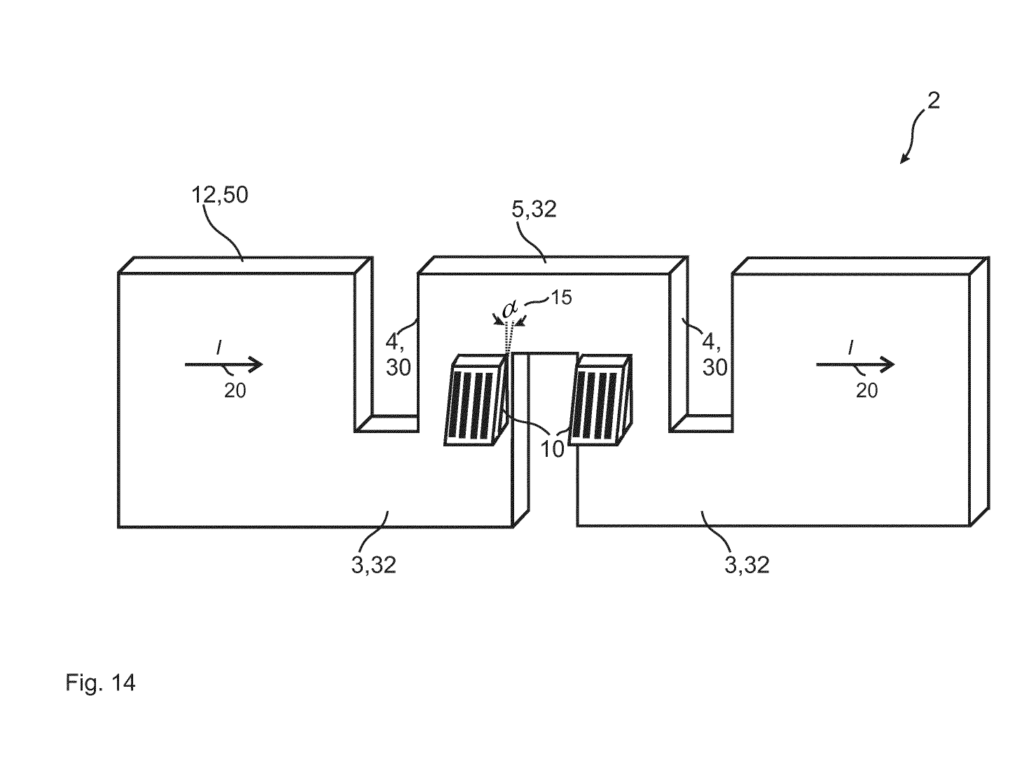

Instead of a sensor element 10 it is also possible, as is shown in FIG. 13, for a plurality of sensor elements 10 to be arranged in the region of the U-shaped conductor element 2, which then, in accordance with an aspect of the invention, are arranged at an inclination to the conductor element 17 assigned to the sensor elements 10. An embodiment of this type is also represented in FIG. 14, where the angle of inclination α 15 is selected in accordance with the configuration illustrated in FIG. 7. To adjust the angle of inclination 15 in a defined manner, a fastening means 8 can be designed which is fastened on the conductor 12 or on the leg 4 in such a way as to provide the desired angular orientation.

An optimized positioning of the sensor element 10 relative to the conductor elements 3, 4 and 5 can on the one hand be determined purely on the basis of experience or empirical trials, or on the other hand by means of a numerical field simulation of the static magnetic field or of a transient field distribution with a specified conductor structure 12. Numerical simulation methods, especially those based on finite elements or finite differences, which can determine a magnetic field distribution for a specified flow of current through a specified electrical conductor configurations 12, are suitable for this purpose. On the basis of the parasitic magnetic field components which can for example be considered individually by the insertion of the current only in the conductor sections 32 parasitic to current measurement, it is thus possible to determine a suitable orientation of the sensor element which can involve a modified angle of inclination, in a defined height relationship of the conductor elements to one another, in a parasitic magnetic field compensation, or in a combination of these.

1. Arrangement for magnetic-field-based measurement of electrical currents by means of at least one magnetic-field-sensitive sensor element in an angled, in particular U-shaped, conductor element, comprising at least one conductor section active in current measurement and at least one conductor section parasitic to current measurement, wherein the sensor element has at least one sensitivity direction in which magnetic field components cause a major change in the sensor value, where the sensor element is arranged in a region of the conductor section active in current measurement and is, inclined relative to the conductor section parasitic to current measurement and/or vertically displaced relative to the conductor section parasitic to current measurement such that the magnetic field of the conductor section active in current measurement is oriented substantially in the sensitivity direction, and the magnetic field of the conductor section parasitic to current measurement is oriented substantially not in the sensitivity direction, in particular at right angles to the sensitivity direction.

2. Arrangement according to claim 1, wherein the at least one sensor element is oriented inclined to the conductor element assigned to the sensor element.

3. Arrangement according to claim 2, wherein the angle of inclination is selected such that that the parasitic components of the magnetic field that lie in the sensitivity direction of the sensor element and are generated by currents in the connecting bridge between the two legs of the U-shaped conductor section are minimized at the location of the sensor element, or that the angle of inclination is selected such that the parasitic components of the resulting magnetic field that lie in the sensitivity direction of the sensor element fand are generated by the superposition of the magnetic field generated by currents in the connecting bridge between the two legs of the U-shaped conductor element and of the magnetic field generated by currents through the connecting lines to the U-shaped conductor element are minimized at the location of the sensor element.

4. Arrangement according to one of the preceding claims, wherein the sensor element is a gradient sensor or a sensor measuring absolute field, where the sensor element is preferably a magnetoresistive sensor.

5. Arrangement according to one of the preceding claims, wherein the angled, preferably U-shaped conductor element is formed by slots in a flat and straight section of conductor, where in particular the two legs of the U-shaped conductor element are aligned parallel to one another.

6. Arrangement according to one of the preceding claims, wherein at least one fastening means is provided which receives the at least one sensor element and is fixed in an inclined position relative to the associated U-shaped conductor element.

7. Arrangement according to claim 6, wherein the fastening means engages into or onto a straight section of conductor or a U-shaped conductor element.

8. Arrangement according to claim 6, wherein the fastening means comprises at least one electrically conductive track, which electrically contacts at least one sensor element.

9. Arrangement according to claim 6, wherein the fastening means is designed in MID technology (Molded Interconnected Devices).

10. Arrangement according to claim 6, wherein electronic components assigned to the at least one sensor element are arranged on the fastening means.

11. Arrangement according to claim 6, wherein a protective sheath is provided at least around the fastening means with the at least one sensor element, where the sheath preferably encloses parts of the U-shaped conductor element.

12. Arrangement according to one of the preceding claims, wherein the three-dimensional spatial arrangement of sensor element and conductor section parasitic to current measurement relative to one another is such that the sensitivity direction at the location of the sensor element is aligned at right angles to a tangent of a closed magnetic field line of the parasitic magnetic field generated by the current distribution of the conductor section parasitic to current measurement.

13. Arrangement according to claim 12, wherein the conductor element is a punched and bent metal component, where the centre of gravity of the current density distribution through the conductor section parasitic to current measurement and a magnetic-field-neutral orientation plane, whose normal is at right angles to the sensitivity direction, lie substantially at the same vertical level z at the location of the sensor element.

14. Arrangement according to claim 12, wherein the sensor element is arranged on a bent conductor section active in current measurement (4, 30, 52), whereby the centre of gravity of the current density distribution through the conductor section parasitic to current measurement and a magnetic-field-neutral orientation plane, whose normal is at right angles to the sensitivity direction, lie substantially at the same vertical level z at the location of the sensor element.

15. Arrangement according to one of claims 12 to 14, wherein conductor sections active in and parasitic to current measurement are arranged on or in a Printed Circuit Board (PCB) arrangement, in particular in a multi-layer PCB on layers that are vertically displaced.
